(19) United States
(12) Patent Application Publication
(10) Pub. No.: US 2022/0393422 A1
(43) Pub. Date: Dec. 8, 2022

(54) LIGHT TRANSMISSION UNIT, LASER APPARATUS, AND METHOD FOR MANUFACTURING ELECTRONIC DEVICES

(71) Applicant: Gigaphoton Inc., Tochigi (JP)

(72) Inventors: Natsuhiko KOUNO, Oyama-shi (JP); Masato MORIYA, Oyama-shi (JP)

(73) Assignee: Gigaphoton Inc., Tochigi (JP)

(21) Appl. No.: 17/817,820

(22) Filed: Aug. 5, 2022

Related U.S. Application Data
(63) Continuation of application No. PCT/JP2020/011326, filed on Mar. 16, 2020.

(51) Int. Cl. H01S 3/13; H01S 3/08; H01S 3/11; H01S 3/23; G03F 7/20

(52) U.S. Cl. CPC H01S 3/1305; H01S 3/08059; H01S 3/11; H01S 3/2366; G03F 7/2006; H01S 3/225

(57) ABSTRACT

A laser apparatus according to an aspect of the present disclosure includes a laser oscillator that outputs pulsed laser light, a deformable mirror including a deformer that deforms a reflective surface, a first processor that drives the deformer during the period for which the reflective surface reflects the pulsed laser light, a homogenizer that homogenizes the pulsed laser light reflected off the deformable mirror, and a spectrum measuring instrument that measures the spectrum of the pulsed laser light homogenized by the homogenizer.

### CROSS-REFERENCE TO RELATED APPLICATIONS

The present application is a continuation application of International Application No. PCT/JP2020/011326, filed on Mar. 16, 2020, the entire contents of which are hereby incorporated by reference.

### BACKGROUND

### 1. Technical Field

The present disclosure relates to a light transmission unit, a laser apparatus, and a method for manufacturing electronic devices.

### 2. Related Art

In recent years, a semiconductor exposure apparatus is required to improve the resolution thereof as semiconductor integrated circuits are increasingly miniaturized and highly integrated. To this end, reduction in the wavelength of light outputted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

Light from spontaneously oscillating KrF and ArF excimer laser apparatuses has a wide spectral linewidth ranging from 350 to 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light outputted from the gas laser apparatus needs to be narrow enough to make the chromatic aberrations negligible. To this end, a line narrowing module (LNM) including a line narrowing element (such as etalon and grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

[PTL 1] JP-A-2008-277617
[PTL 2] JP-A-2006-184077
[PTL 3] U.S. Patent Publication No. 2008/0106720
[PTL 4] JP-T-2011-507042

### SUMMARY

A light transmission unit according to an aspect of the present disclosure includes a deformable mirror including a deformer configured to deform a reflection surface during a period for which the reflection surface reflects pulsed laser light, and a homogenizer configured to homogenize the pulsed laser light reflected off the deformable mirror.

A laser apparatus according to another aspect of the present disclosure includes a laser oscillator configured to output pulsed laser light, a deformable mirror including a deformer configured to deform a reflective surface, a first processor configured to drive the deformer during a period for which the reflective surface reflects the pulsed laser light, a homogenizer configured to homogenize the pulsed laser light reflected off the deformable mirror, and a spectrum measuring instrument configured to measure a spectrum of the pulsed laser light homogenized by the homogenizer.

A electronic device manufacturing method according to another aspect of the present disclosure is a method for manufacturing electronic devices, the method including generating pulsed laser light by using a laser apparatus, outputting the pulsed laser light to an exposure apparatus, and exposing a light sensitive substrate to the pulsed laser light in the exposure apparatus to manufacture the electronic devices, the laser apparatus including a laser oscillator configured to output the pulsed laser light, a deformable mirror including a deformer configured to deform a reflective surface, a first processor configured to drive the deformer during a period for which the reflection surface reflects the pulsed laser light, a homogenizer configured to homogenize the pulsed laser light reflected off the deformable mirror, and a spectrum measuring instrument configured to measure a spectrum of the pulsed laser light homogenized by the homogenizer.

### BRIEF DESCRIPTION OF THE DRAWINGS

Embodiments of the present disclosure will be described below only by way of example with reference to the accompanying drawings.

FIG. 1 shows an example of a speckle image as a result of capture of an image of a pattern formed of bright and dark spots.

FIG. 2 shows a histogram of the bright and dark portions of the speckle image shown in FIG. 1.

FIG. 3 describes a spectral linewidth.

FIG. 4 describes the definition of E95.

FIG. 5 shows the configuration of an excimer laser apparatus.

FIG. 6 shows the configuration of an optical fiber.

FIG. 7 is a cross-sectional view of the optical fiber taken along the line 7-7 in FIG. 6.

FIG. 8 shows the configuration of a spectrum measuring instrument.

FIG. 9 describes interference fringes and a fringe pattern.

FIG. 10 describes speckle noise and the fringe pattern.

FIG. 11 describes vibration of the optical fiber produced by a fiber swinging mechanism.

FIG. 12 shows time-course changes in the emission intensity of pulsed laser light corresponding to one pulse and vibration of a light exiting end of the optical fiber within the period of the one pulse.

FIG. 13 shows time-course changes in the emission intensity of the pulsed laser light corresponding to one pulse and the amplitude of the vibration within the light emission period of the one pulse.

FIG. 14 shows the configuration of an excimer laser apparatus.

FIG. 15 shows the configuration of a deformable mirror.

FIG. 16 shows part of the configuration of a light transmission unit in detail.

FIG. 17 shows cross-sectional views of the optical fiber.

FIG. 18 describes the timing at which a reflective surface is vibrated and deformed.

FIG. 19 describes how the pulsed laser light is reflected under the control of the deformable mirror.

FIG. 20 shows the relationship between the pulse width of the pulsed laser light and an SC reduction ratio.

FIG. 21 shows an example of part of the configuration of the light transmission unit.

FIG. 22 shows an example of the part of the configuration of the light transmission unit.

FIG. 23 shows another example of the part of the configuration of the light transmission unit.

FIG. 24 shows another example of the part of the configuration of the light transmission unit.

FIG. 25 shows an example of a part of the configuration of the light transmission unit.

FIG. 26 shows an example of the part of the configuration of the light transmission unit.

FIG. 27 shows cross-sectional views of the optical fiber.

FIG. 28 shows part of the configuration of the excimer laser apparatus.

FIG. 29 schematically shows an example of the configuration of an exposure apparatus.

### DETAILED DESCRIPTION

<Contents>

1. Description of terms
1.1 Definition of speckle contrast

### 1.2 Definition of E95

2. Overview of laser system
2.1 Configuration of laser system
2.1.1 Configuration of optical fiber
2.1.2 Configuration of spectrum measuring instrument

### 2.2 Operation

2.2.1 Fringe pattern

### 3. Problems

### 4. First Embodiment

### 4.1 Configuration

4.1.1 Configuration of deformable mirror
4.1.2 Details of configuration of light transmission unit
4.1.3 Configuration of optical fiber

### 4.2 Operation

4.3 Effects and advantages

### 5. Second Embodiment

### 5.1 Configuration

### 5.2 Operation

5.3 Effects and advantages

### 6. Third Embodiment

### 6.1 Configuration

### 6.2 Operation

6.3 Effects and advantages

### 7. Fourth Embodiment

### 7.1 Configuration

### 7.2 Operation

7.3 Effects and advantages
8. Method for manufacturing electronic device

### 9. Others

Embodiments of the present disclosure will be described below in detail with reference to the drawings. The embodiments described below show some examples of the present disclosure and are not intended to limit the contents of the present disclosure. Further, all configurations and operations described in the embodiments are not necessarily essential as configurations and operations in the present disclosure. The same component has the same reference character, and no redundant description of the same component will be made.

### 1. Description of Terms

The terms used in the present specification are defined as follows.

1.1 Definition of Speckle Contrast

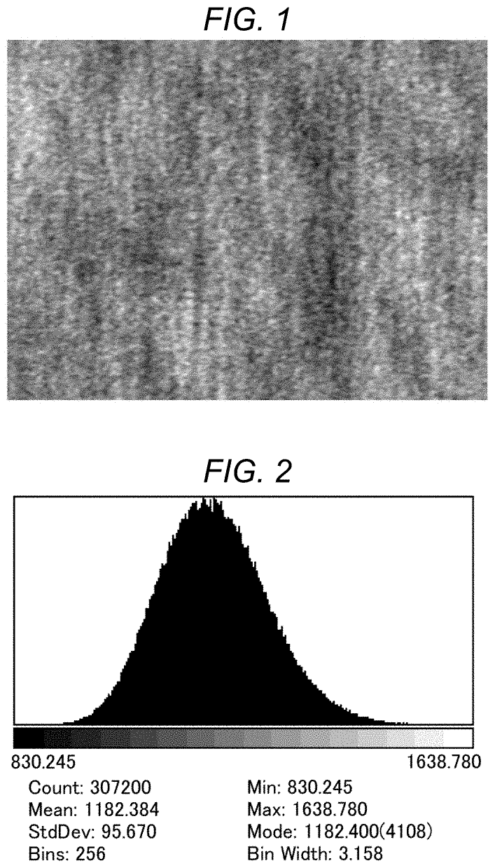

Speckles are bright and dark spots produced when laser light is scattered by a random medium. FIG. 1 shows an example of a speckle image as a result of capture of an image of a pattern formed of bright and dark spots. FIG. 2 shows a histogram of the bright and dark portions of the speckle image shown in FIG. 1.

Speckle contrast SC is typically used as a speckle evaluation index. Let σ be the standard deviation of the intensities of the speckle image, and I macron (I accompanied by macron thereabove) be the average of the intensities of the speckle image, and the speckle contrast SC can be expressed by Expression (1) below.

$$SC = \frac{σ}{\overline{I}} \qquad ( 1 )$$

1.2 Definition of E95

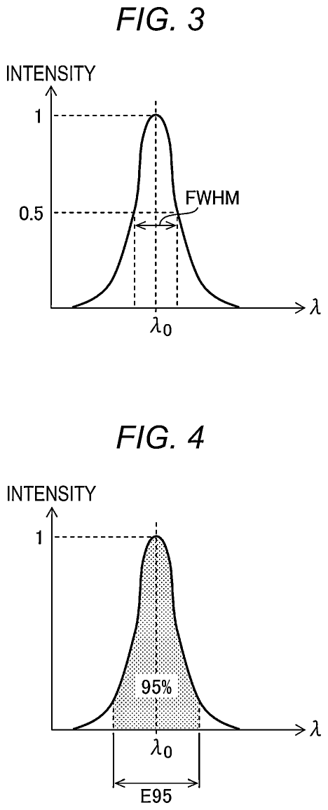

FIG. 3 describes a spectral linewidth. The spectral linewidth is the full width of the spectrum waveform of laser light at a light quantity threshold, as shown in FIG. 3. It is assumed in the present specification that the relative value of each light quantity threshold with respect to the light quantity peak value is called a linewidth threshold Thresh (0<Thresh<1). For example, one half of the peak value is called a linewidth threshold of 0.5. The full width W/2 of the spectrum waveform at the linewidth threshold 0.5 is particularly called a full width at half maximum (FWHM).

FIG. 4 describes the definition of E95. Spectral purity, for example, 95% purity E95 is a full width W95%, which is the width of the portion that accounts for 95% of the overall spectral energy around a wavelength Xo, as shown in FIG. 4, and Expression (2) below is satisfied.

$$\frac{{\int }_{- \frac{Δ λ}{2}}^{\underline{\frac{Δ λ}{2}}} g ( λ + {λ}_{0} ) d λ}{{\int }_{- ∞}^{∞} g ( λ + {λ}_{0} ) d λ} = 0.95 \qquad ( 2 )$$

Unless otherwise particularly stated, the description will be made in the present specification on the assumption that the spectral purity is E95.

### 2. Overview of Laser System

2.1 Configuration of Laser System

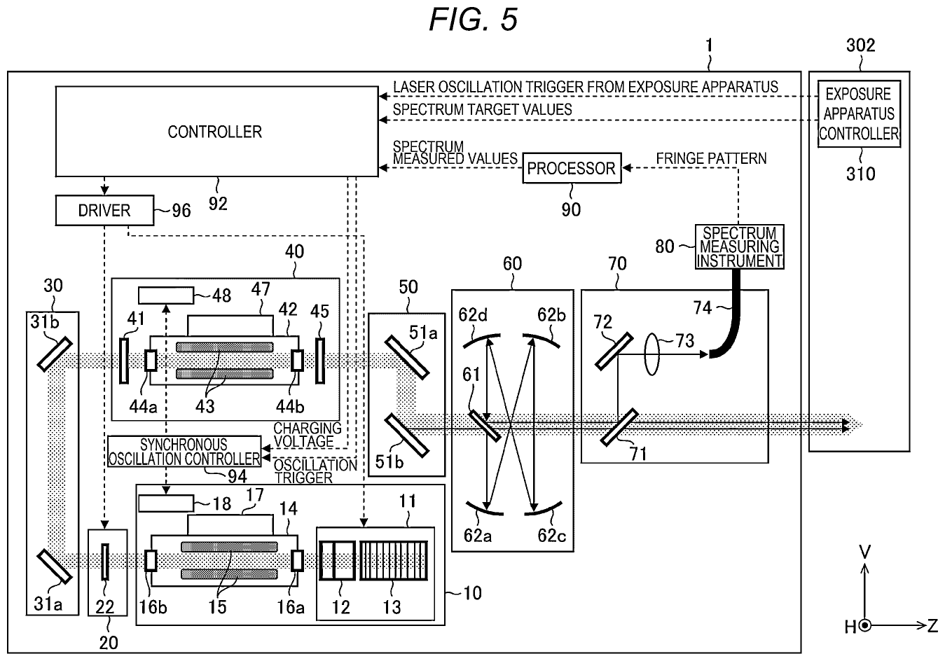

FIG. 5 shows the configuration of an excimer laser apparatus 1. The excimer laser apparatus 1 is a narrowed-line gas laser apparatus that generates pulsed laser light having an ultraviolet wavelength. The excimer laser apparatus 1 includes a master oscillator (MO) 10, a spectrum changer 20, an MO beam steering unit 30, a power oscillator (PO) 40, a PO beam steering unit 50, an optical pulse stretcher 60, a light transmission unit 70, a spectrum measuring instrument 80, a processor 90, a controller 92, a synchronous oscillation controller 94, and a driver 96, as shown in FIG. 5.

The MO 10 (example of narrowed-line gas laser apparatus) includes an LNM 11, a chamber 14, a power supply 17, and a charger 18.

The LNM 11 includes a prism 12 and a grating 13, which narrow the spectral linewidth. The prism 12 functions as a beam expander. The prism 12 is placed on a rotary stage that is not shown and is disposed so as to change the angle of incidence of light to be incident on the grating 13 when the rotary stage is rotated. The grating 13 may be disposed in the Littrow arrangement, which causes the angle of incidence of the light incident on the grating 13 to be equal to the angle of diffraction of the light diffracted by the grating 13.

The chamber 14 is disposed in the optical path of an optical resonator that will be described later. The chamber 14 includes a pair of discharge electrodes 15 and two windows 16a and 16b, through which the pulsed laser light passes. The chamber 14 accommodates an excimer laser gas. The excimer laser gas may contain, for example, an Ar or Kr gas as a rare gas, an F₂ gas as a halogen gas, and an Ne gas as a buffer gas.

The power supply 17 includes a charging capacitor and a switch, none of which is shown. The charger 18 holds electrical energy used to apply a high voltage to the gap between the pair of discharge electrodes 15. The charger 18 is connected to the charging capacitor provided in the power supply 17.

The spectrum changer 20 includes an output coupler (OC) 22. The OC 22 is a reflective mirror having a reflectance ranging from 40% to 60%. The OC 22 and the LNM11 are arranged so as to form an optical resonator.

The MO beam steering unit 30 includes highly reflective mirrors 31a and 31b. The highly reflective mirrors 31a and 31b are so disposed that the pulsed laser light outputted from the MO 10 enters the PO 40.

The PO 40 includes a rear mirror 41, a chamber 42, an OC 45, a power supply 47, and a charger 48.

The rear mirror 41 is a reflective mirror having a reflectance ranging from 80% to 90%. The OC 45 is a reflective mirror having a reflectance ranging from 20% to 30%. The rear mirror 41 and the OC 45 are arranged so as to form an optical resonator.

The chamber 42 is disposed in the optical path of the optical resonator. The chamber 42 includes a pair of discharge electrodes 43 and two windows 44a and 44b, through which the pulsed laser light passes. The chamber 42 accommodates an excimer laser gas. The chamber 42 has the same configuration as that of the chamber 14.

The power supply 47 includes a charging capacitor and a switch, none of which is shown. The charger 48 is a DC power supply apparatus that charges the charging capacitor in the power supply 47 with a predetermined voltage.

The PO beam steering unit 50 includes highly reflective mirrors 51a and 51b. The highly reflective mirrors 51a and 51b are so disposed that the pulsed laser light outputted from the PO 40 enters the OPS 60.

The OPS 60 is an apparatus that stretches the pulse width of the pulsed laser light outputted from the PO beam steering unit 50. The OPS 60 includes a beam splitter (BS) 61 and four concave mirrors 62.

The BS 61 is disposed in the optical path of the pulsed laser light outputted from the PO beam steering unit 50. The BS 61 is a reflective mirror that transmits part of the pulsed laser light incident thereon and reflects the other part of the pulsed laser light. The reflectance of the BS 61 is about 60%. The BS 61 is disposed so as to cause the pulsed laser light having passed through the BS 61 to enter the light transmission unit 70.

The four concave mirrors 62 form a delay optical path that delays the pulsed laser light reflected off the BS 61. The four concave mirrors 62 are so arranged that the laser light reflected off the BS 61 is reflected off the four concave mirrors 62 and focused again at the BS 61.

The four concave mirrors 62 is formed of a concave mirror 62a, a concave mirror 62b, a concave mirror 62c, and a concave mirror 62d, which each have a focal length F₁.

The concave mirrors 62a and 62b are so arranged that the pulsed laser light reflected off the BS 61 is reflected off the concave mirror 62a and incident on the concave mirror 62b. The concave mirrors 62c and 62d are so arranged that the pulsed laser light reflected off the concave mirror 62b is reflected off the concave mirror 62c and incident on the concave mirror 62d. Furthermore, the concave mirror 62d is so disposed that the pulsed laser light reflected off the concave mirror 62d is incident on the BS 61.

The above description has been made with reference to the case where the OPS 60 includes a single-stage OPS, and the OPS 60 may instead include multi-stage OPSes, that is, two or more OPSes.

The light transmission unit 70 includes a BS 71, a highly reflective mirror 72, a focusing lens 73, and an optical fiber 74.

The BS 71 is disposed in the optical path of the pulsed laser light outputted from the OPS 60. The BS 71 is a reflective mirror that transmits part of the pulsed laser light incident thereon and reflects the other part of the pulsed laser light. The BS 71 is disposed so as to cause the pulsed laser light having passed through the BS 71 to enter an exposure apparatus 302.

The highly reflective mirror 72 is disposed so as to reflect the pulsed laser light reflected off the BS 71 and cause the reflected pulsed laser light to enter the focusing lens 73. The focusing lens 73 is disposed so as to focus the pulsed laser light incident thereon and cause the focused pulsed laser light to enter the optical fiber 74.

The pulsed laser light having entered the optical fiber 74 is inputted to the spectrum measuring instrument 80.

The spectrum measuring instrument 80 is communicatively connected to the processor 90. The controller 92 is communicatively connected to the processor 90, the synchronous oscillation controller 94, the driver 96, and an exposure apparatus controller 310 of the exposure apparatus 302.

The synchronous oscillation controller 94 is communicatively connected to the power supply 17, the charger 18, the power supply 47, and the charger 48. The driver 96 is communicatively connected to the LNM 11 and the spectrum changer 20.

2.1.1 Configuration of Optical Fiber

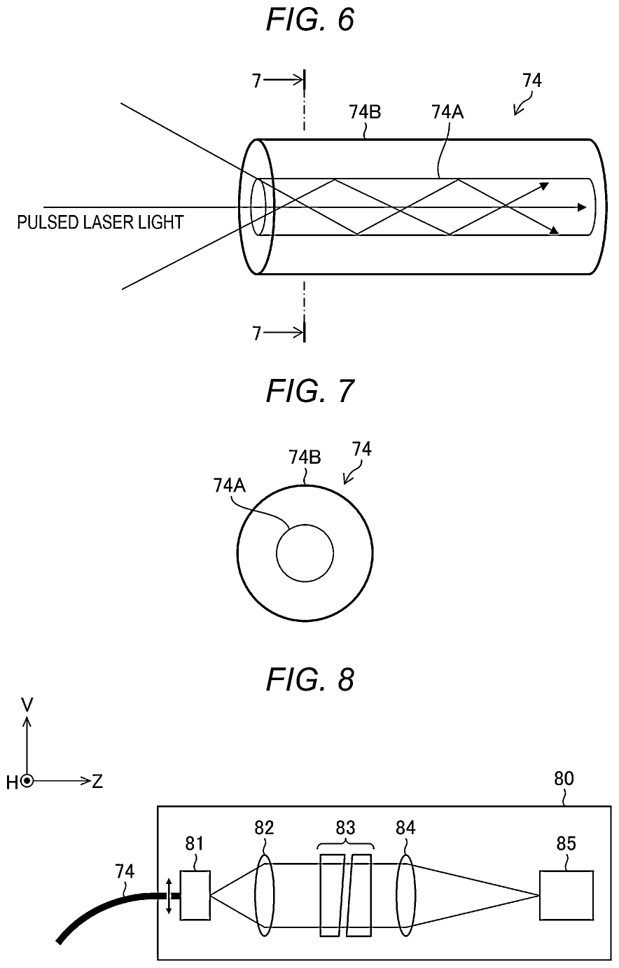

FIG. 6 shows the configuration of the optical fiber 74. FIG. 7 is a cross-sectional view of the optical fiber taken along the line 7-7 in FIG. 6. The optical fiber 74 includes a core 74A, which forms a waveguide along which the pulsed laser light is guided, and a cladding 74B, which surrounds the core 74A, as shown in FIGS. 6 and 7. The core 74A of the optical fiber 74 has a circular cross-sectional shape.

2.1.2 Configuration of Spectrum Measuring Instrument

FIG. 8 shows the configuration of the spectrum measuring instrument 80. The spectrum measuring instrument 80 includes a fiber swinging mechanism 81, a collimation lens 82, an etalon 83, a focusing lens 84, and a sensor 85, as shown in FIG. 8.

The fiber swinging mechanism 81 holds the light exiting end of the optical fiber 74 in such a way that the light exiting end faces a direction Z and swings the optical fiber 74 in a direction V. The fiber swinging mechanism 81 may keep swinging the optical fiber 74. The direction in which the optical fiber 74 is swung is not limited to the direction V, and only needs to be a direction perpendicular to the direction Z, which is the light exiting direction.

The collimation lens 82 converts the pulsed laser light having exited out of the optical fiber 74 into parallelized light. The etalon 83 spectrally separates the pulsed laser light incident thereon and causes the pulsed laser light to produce interference fringes. The focusing lens 84 focuses the light having exited out of the etalon 83 at the light receiving surface of the sensor 85. The sensor 85 acquires a fringe pattern from the interference fringes produced by the pulsed laser light focused at the light receiving surface.

2.2 Operation

The controller 92 accepts a laser oscillation trigger from the exposure apparatus controller 310 of the exposure apparatus 302.

The synchronous oscillation controller 94 accepts a charging voltage and an oscillation trigger signal from the controller 92. The synchronous oscillation controller 94 controls the voltages applied to the chargers 18 and 48 based on the accepted charging voltage. The synchronous oscillation controller 94 further controls the switch in the power supply 17 and the switch in the power supply 47 in synchronization with the oscillation trigger signal.

When the switch in the power supply 17 is changed from the turned-off state to the turned-on state, the power supply 17 generates a pulsed high voltage from the electric energy held in the charger 18 and applies the high voltage to the gap between the pair of discharge electrodes 15. Similarly, when the switch in the power supply 47 is changed from the turned-off state to the turned-on state, the power supply 47 generates a pulsed high voltage from the electric energy held in the charger 48 and applies the high voltage to the gap between the pair of discharge electrodes 43.

When the high voltage is applied to the gap between the pair of discharge electrodes 15, the insulation between the pair of discharge electrodes 15 is broken down, and discharge occurs. The energy of the discharge excites the excimer laser gas in the chamber 14, and the optical resonator formed of the OC 22 and the LNM 11 outputs narrowed-line pulsed laser light from the OC 22. The MO beam steering unit 30 causes the pulsed laser light to be incident as seed light on the rear mirror 41 of the PO 40.

In synchronization with the timing at which the seed light having passed through the rear mirror 41 enters the PO 40, the high voltage is applied to the gap between the pair of discharge electrodes 43 to generate discharge in the chamber 42. As a result, the laser gas is excited, the seed light is amplified by the Fabry-Perot-type optical resonator formed of the OC 45 and the rear mirror 41, and the amplified pulsed laser light is outputted from the OC 45. The pulsed laser light outputted from the OC 45 enters the OPS 60 via the PO beam steering unit 50. The pulsed laser light having passed through the OPS 60, which has stretched the pulse width of the pulsed laser light, enters the light transmission unit 70.

The BS 71 of the light transmission unit 70 causes part of the pulsed laser light incident thereon to exit out of the excimer laser apparatus 1 and causes the other part of the pulsed laser light to be incident on the highly reflective mirror 72. The pulsed laser light outputted from the excimer laser apparatus 1 is inputted to the exposure apparatus 302.

The pulsed laser light incident on the highly reflective mirror 72 is reflected off the highly reflective mirror 72, then focused by the focusing lens 73, and incident on one end of the optical fiber 74. The pulsed laser light incident on the one end of the optical fiber 74 is inputted to the spectrum measuring instrument 80 and exits via the other end of the optical fiber 74 swung by the fiber swinging mechanism 81.

The pulsed laser light having exited out of the optical fiber 74 is converted into parallelized light by the collimation lens 82, is then spectrally separated by the etalon 83, is focused by the focusing lens 84, and forms interference fringes at the light receiving surface of the sensor 85. The sensor 85 receives the interference fringes and detects a fringe pattern.

The fringe pattern detected by the sensor 85 is sent to the processor 90. The processor 90 (example of second processor) calculates the center wavelength, the spectral linewidth, the E95 width, and other factors of the pulsed laser light from the received fringe pattern. The calculation of the factors described above is performed on a fringe pattern averaged over a plurality of pulses.

The measured values calculated by the processor 90, the center wavelength, the spectral linewidth, the E95 width, and other factors of the pulsed laser light, are sent to the controller 92.

The controller 92 accepts spectrum target values from the exposure apparatus controller 310 of the exposure apparatus 302. The controller 92 controls the spectrum changer 20 and the LNM 11 via the driver 96 in such a way that the measured values approach the spectral target values.

2.2.1 Fringe Pattern

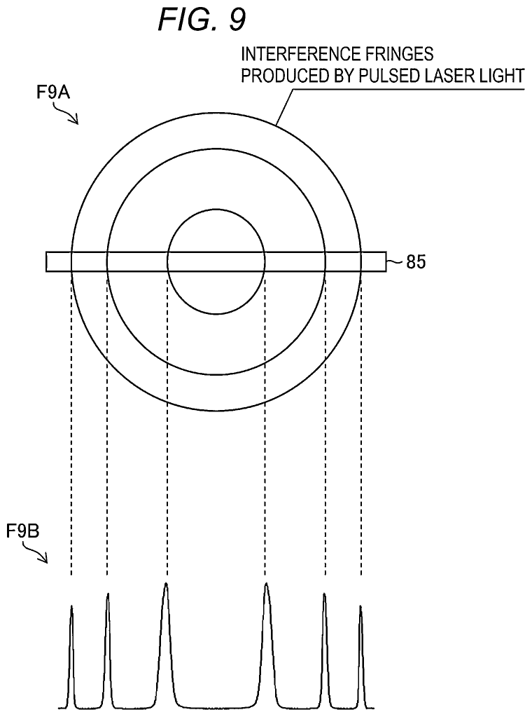

FIG. 9 describes the interference fringes and the fringe pattern. F9A in FIG. 9 shows an example of the positional relationship between the interference fringes formed by the pulsed laser light and the light receiving surface of the sensor 85, and F9B in FIG. 9 shows an example of the fringe pattern detected by the sensor 85 having received the interference fringes shown in F9A. In the fringe pattern, the positions of the interference fringes are expressed by signal intensities.

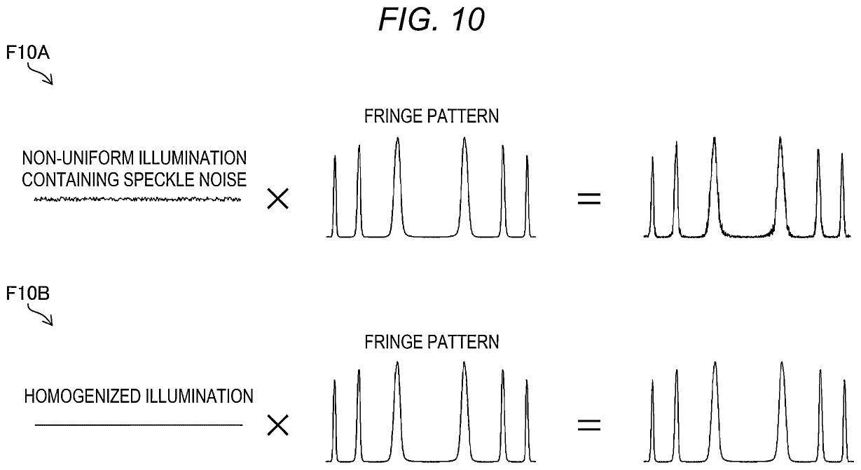

FIG. 10 describes speckle noise and the fringe pattern. F10A in FIG. 10 shows a case where a fringe pattern is detected from interference fringes produced by non-uniform illumination containing speckle noise, and F10B in FIG. 10 shows a case where a fringe pattern is detected from interference fringes produced by homogenized illumination.

The fringe pattern shown in F10A contains speckle noise. On the other hand, the fringe pattern shown in F10B has reduced speckle noise.

When the fiber swinging mechanism 81 does not swing the optical fiber 74, the pulsed laser light contains speckle noise, resulting in a fringe pattern similar to the fringe pattern shown in F10A. When the fiber swinging mechanism 81 swings the optical fiber 74 and a plurality of pulses are averaged into homogenized light, speckle noise is reduced, and a fringe pattern similar to the fringe pattern shown in F10B is achieved.

Swinging the optical fiber 74 with the aid of the fiber swinging mechanism 81 and averaging a plurality of pulses thus allow reduction in speckle noise in the fringe pattern.

### 3. Problems

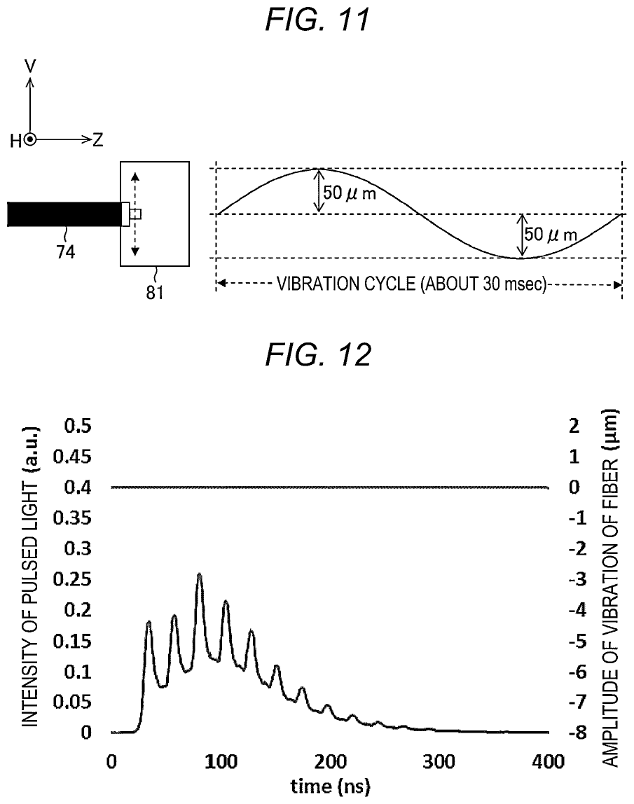

FIG. 11 describes vibration of the optical fiber 74 produced by the fiber swinging mechanism 81. The swing motion produced by the fiber swinging mechanism 81 causes the light exiting end of the optical fiber 74 to vibrate by about ±50 μm in the direction V in a cycle of 30 milliseconds, as shown in FIG. 11. The vibration changes the optical path of the pulsed laser light that exits via the light exiting end of the optical fiber 74 to provide the effect of changing the speckles formed at the light receiving surface of the sensor 85. The effect allows stable precision of the spectrum measurement because the fringe pattern averaged over a plurality of pulses has reduced speckle noise.

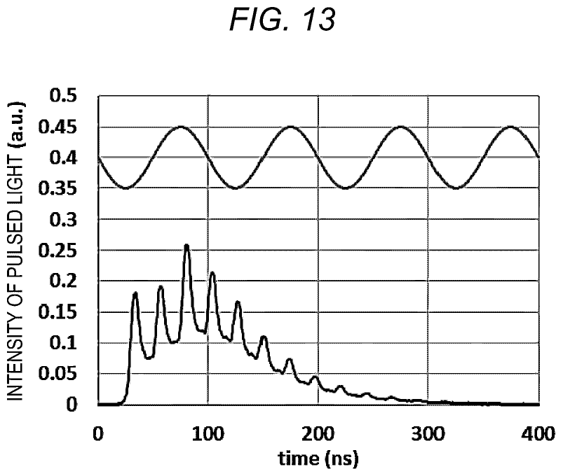

FIGS. 12 and 13 show time-course changes in the emission intensity of the pulsed laser light corresponding to one pulse outputted from the PO 40 and then stretched by the OPS 60. FIG. 12 further shows the amplitude of the vibration of the light exiting end of the optical fiber 74 produced by the fiber swinging mechanism 81 within the period of the one pulse (about 400 ns). The change in the amplitude of the vibration of the light exiting end of the optical fiber 74 within the light emission period corresponding to one pulse is nearly 0 μm, so that the speckle noise reduction effect provided by the vibration of the optical fiber 74 cannot be achieved within the light emission period corresponding to one pulse, as shown in FIG. 12.

In recent years, a demand for high-speed wavelength control has increased. To perform the wavelength control at high speed, there is a need for a technology for performing highly accurate spectrum measurement on a pulse basis without averaging over a plurality of pulses. To perform highly precise spectrum measurement, it is necessary to acquire a fringe pattern containing speckle noise reduced on a pulse basis. It is therefore necessary to employ a strategy that allows vibration of the optical path of the laser light within the light emission period corresponding to one pulse, as shown, for example, in FIG. 13.

### 4. First Embodiment

### 4.1 Configuration

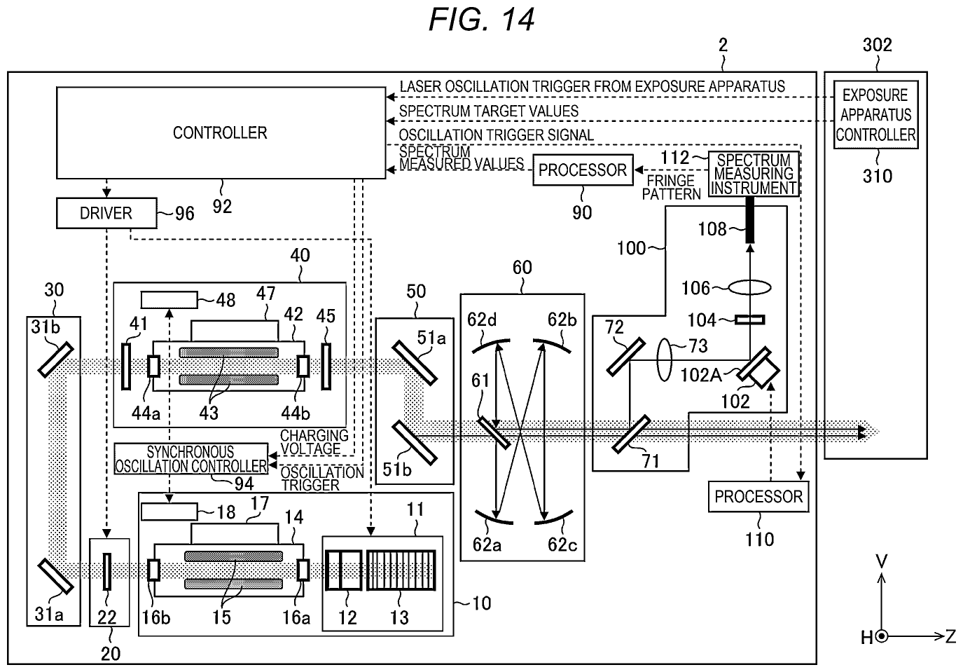

FIG. 14 shows the configuration of an excimer laser apparatus 2 according to a first embodiment. The excimer laser apparatus 2 includes a light transmission unit 100 and a processor 110. The light transmission unit 100 includes a deformable mirror 102, a diffuser 104, a focusing lens 106, and an optical fiber 108.

The deformable mirror 102 has a deformable reflective surface 102A. The deformable mirror 102 is so disposed that the pulsed laser light reflected off the BS 71 and the highly reflective mirror 72 is incident on the reflective surface 102A.

The focusing lens 73 (example of first focusing optical element) is disposed in the optical path between the highly reflective mirror 72 and the deformable mirror 102.

The diffuser 104 (example of homogenizer) is an optical element that diffuses the pulsed laser light incident thereon and causes the diffused light to exit. The diffuser 104 is desirably a corroded diffuser having high transmittance. A corroded diffuser is, for example, a diffuser made of glass and having one side frosted and then corroded with hydrogen fluoride.

The diffuser 104, the focusing lens 106, and the optical fiber 108 are so arranged that the pulsed laser light reflected off the reflective surface 102A of the deformable mirror 102 is incident on one end of the optical fiber 108 via the diffuser 104 and the focusing lens 106. The other end of the optical fiber 108 is connected to the spectrum measuring instrument 112.

The spectrum measuring instrument 112 may not include the fiber swinging mechanism 81 (see FIG. 8).

The processor 110 (example of first processor) is communicatively connected to the controller 92 and the deformable mirror 102.

4.1.1 Configuration of Deformable Mirror

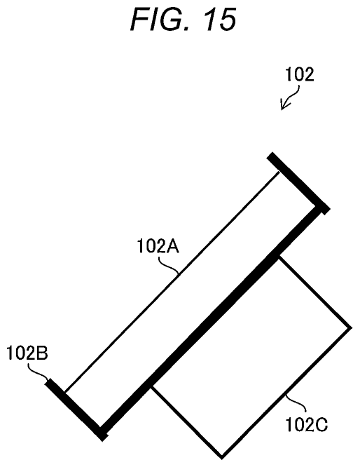

FIG. 15 shows the configuration of the deformable mirror 102. The deformable mirror 102 includes the reflective surface 102A, a mirror holder 102B, which holds the reflective surface 102A, and a vibrator 102C, which vibrates and deforms the reflective surface 102A.

The vibrator 102C (example of deformer) includes a single actuator that is not shown but periodically deforms the shape of the reflective surface 102A into a concave or convex shape by applying a force to the rear side of the reflective surface 102A during the period for which the reflective surface 102A reflects the pulsed laser light. The vibrator 102C may deform each of the shapes of portions of the reflective surface 102A at a plurality of locations thereon into a concave or convex shape. In this case, the vibrator 102C may include a plurality of actuators arranged in a matrix. The actuator that changes the shape of the reflective surface 102A may be any of electrostatically, electromagnetically, hydraulically, piezoelectrically, acoustically, and mechanically driven actuators.

4.1.2 Details of Configuration of Light Transmission Unit

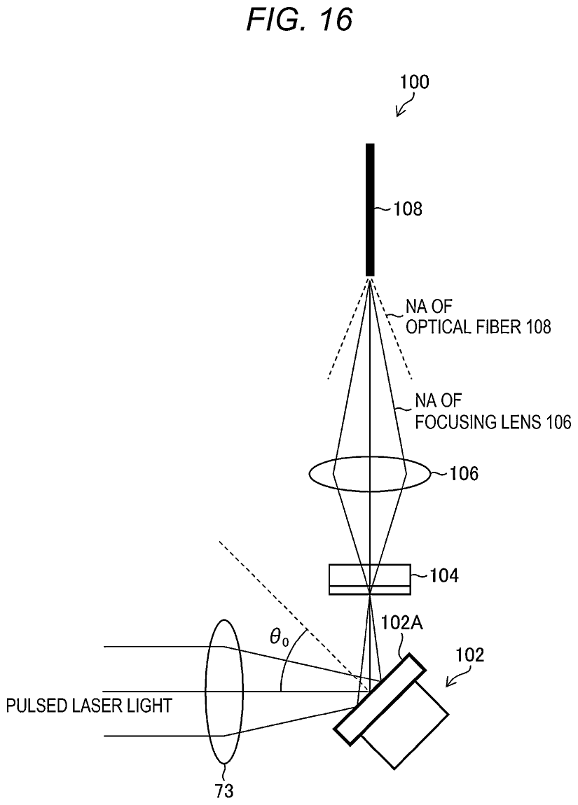

FIG. 16 shows part of the configuration of the light transmission unit 100 in detail.

The deformable mirror 102 is so disposed that an angle of incidence 00 of the pulsed laser light incident from the focusing lens 73 is greater than 0° but smaller than or equal to 45° and the distance between the focusing lens 73 and the reflective surface 102A is shorter than the focal length of the focusing lens 73.

The diffuser 104 is located in a position where the pulsed laser light is focused by the focusing lens 73 when the reflective surface 102A of the deformable mirror 102 is not deformed.

The focusing lens 106 (example of second focusing optical element) is located in a position where the focusing lens 106 can focus the pulsed laser light having spread when passing through the diffuser 104 at the end of the optical fiber 108. The numerical aperture (NA) of the focusing lens 106 is desirably smaller than or equal to the numerical aperture of the optical fiber 108.

4.1.3 Configuration of Optical Fiber

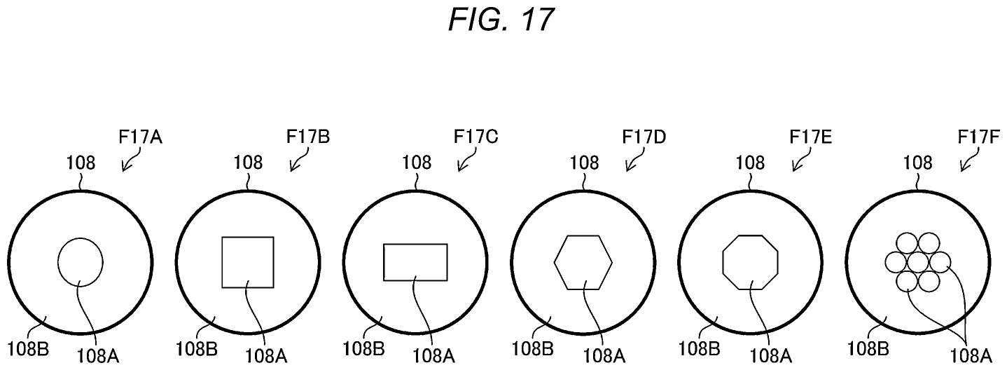

FIG. 17 shows cross-sectional views of the optical fiber 108. The optical fiber 108 includes a core 108A, which forms a waveguide along which the pulsed laser light is guided, and a cladding 108B, which surrounds the core 108A.

F17A, F17B, F17C, F17D, and F17E in FIG. 17 show optical fibers 108 including cores 108A having circular, square, rectangular, hexagonal, and octagonal cross-sectional shapes. F17F shown in FIG. 17 shows an optical fiber 108 including a plurality of cores 108A bundled together. As described above, the core 108A of the optical fiber 108 does not necessarily have a circular cross-sectional shape, and may have a polygonal (square, rectangular, hexagonal, and octagonal) cross-sectional shape, which are effective in illuminance homogenization, or the optical fiber 108 may include a bundle-type core.

4.2 Operation

The processor 110 uses the oscillation trigger signal sent from the controller 92 to control the start timing of the vibrational deformation performed by the vibrator 102C of the deformable mirror 102.

The pulsed laser light is outputted from the MO 10 within a predetermined period starting from the timing at which the oscillation trigger signal starts rising. The predetermined period is, for example, 40 microseconds. The predetermined period is substantially fixed irrespective of the laser oscillation frequency. The vibration of the reflective surface 102A of the deformable mirror 102 is synchronized with the oscillation trigger signal. Having received the oscillation trigger signal, the processor 110 outputs a vibrational deformation instruction to the vibrator 102C. Having received the vibrational deformation instruction, the vibrator 102C vibrates the reflective surface 102A of the deformable mirror 102. The processor 110 outputs the vibrational deformation instruction to vibrate the reflective surface 102A of the deformable mirror 102 for a predetermined period starting from the timing at which the oscillation trigger signal starts rising.

The pulsed laser light outputted by the MO 10 in synchronization with the oscillation trigger signal enters the light transmission unit 100 via the PO beam steering unit 50 and the OPS 60.

Out of the pulsed laser light having entered the light transmission unit 100, the pulsed laser light having passed through the BS 71 is inputted to the exposure apparatus 302. On the other hand, the pulsed laser light reflected off the BS 71 is reflected off the highly reflective mirror 72, then focused by the focusing lens 73, and incident on the reflective surface 102A of the deformable mirror 102. The speckles produced by the pulsed laser light reflected off the reflective surface 102A change because the vibrator 102C of the deformable mirror 102 keeps vibrating and deforming the reflective surface 102A during the period for which the pulsed laser light is reflected off the reflective surface 102A.

The pulsed laser light reflected off the reflective surface 102A is diffused by the diffuser 104, is then focused by the focusing lens 106, and enters the optical fiber 108. The pulsed laser light having passed through the optical fiber 108 is inputted to the spectrum measuring instrument 112.

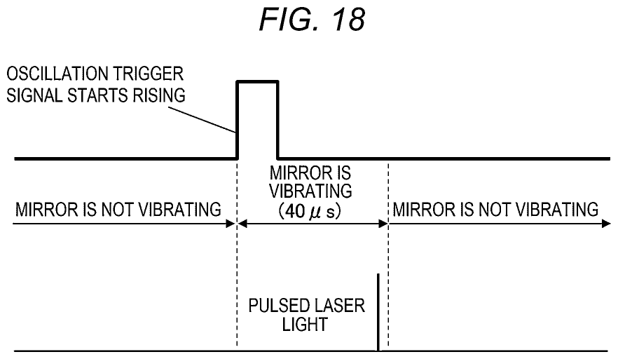

FIG. 18 describes the timing at which the reflective surface 102A is vibrated and deformed. The reflective surface 102A is vibrated and deformed for 40 microseconds from the timing at which the oscillation trigger signal rises, as shown in FIG. 18. The pulsed laser light is emitted within 40 microseconds from the timing at which the oscillation trigger signal rises. The reflective surface 102A of the deformable mirror 102 thus starts being vibrated and deformed before the pulsed laser light is incident thereon and stops being vibrated and deformed after the pulsed laser light exits.

The processor 110 thus synchronizes the timing at which the MO 10 outputs the pulsed laser light (example of generation of pulse laser light) with the timing at which the reflective surface 102A of the deformable mirror 102 starts being vibrated and deformed. The processor 110 may instead synchronize the timing at which the PO 40 amplifies the pulsed laser light with the timing at which the reflective surface 102A of the deformable mirror 102 starts being vibrated and deformed.

The period after which the reflective surface 102A stops being vibrated and deformed is not limited to 40 microseconds (example of fixed period), and the processor 110 may stop vibrating and deforming the reflective surface 102A after the pulsed laser light enters the spectrum measuring instrument 112.

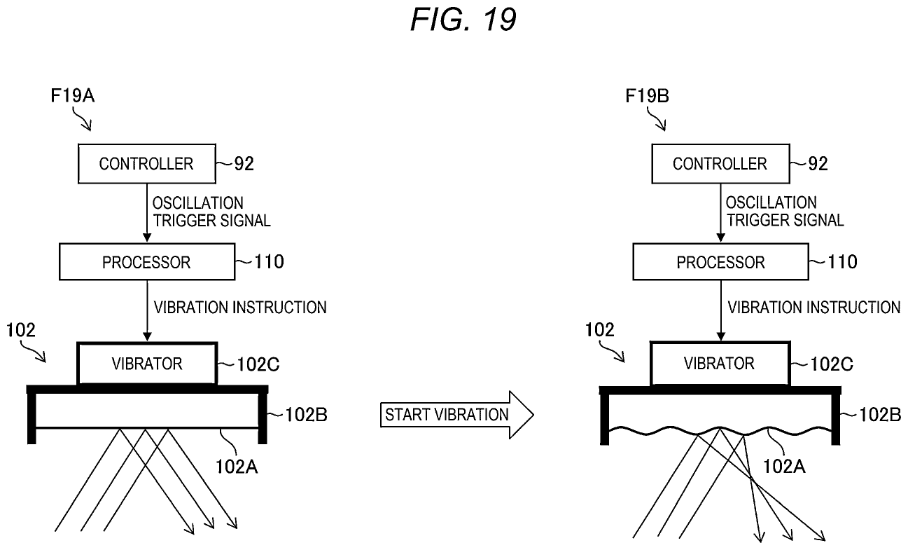

FIG. 19 describes how the pulsed laser light is reflected under the control of the deformable mirror 102. F19A in FIG. 19 shows how the pulsed laser light is reflected when the reflective surface 102A is not deformed, and F19B shows how the pulsed laser light is reflected when the reflective surface 102A is deformed. As shown in F19B, the speckles produced by the pulsed laser light reflected off the reflective surface 102A change when the reflective surface 102A is vibrated and deformed within one pulse of the pulsed laser light. As a result, the speckle noise in the fringe pattern acquired on a pulse basis is reduced.

The reflective surface 102A can vibrate at a frequency of 12 MHz at the maximum with an amplitude that causes the beam spread angle of the reflected pulsed laser light to be 5° at the maximum during the period for which the vibrator 102C receives the vibrational deformation instruction.

4.3 Effects and Advantages

According to the excimer laser apparatus 2, the reflective surface 102A of the deformable mirror 102 can be vibrated within one pulse of pulsed laser light, as shown in FIG. 13. For example, the emission period for which pulsed laser light corresponding to one pulse after passing through the OPS 60 is about 400 nanoseconds, and the deformation of the reflective surface 102A at a predetermined position is about 100 nanoseconds per cycle. As described above, according to the excimer laser apparatus 2, in which the shape of the reflective surface 102A is periodically deformed into a concave or convex shape within one pulse of the pulsed laser light, the speckle noise produced by the pulsed laser light can be reduced.

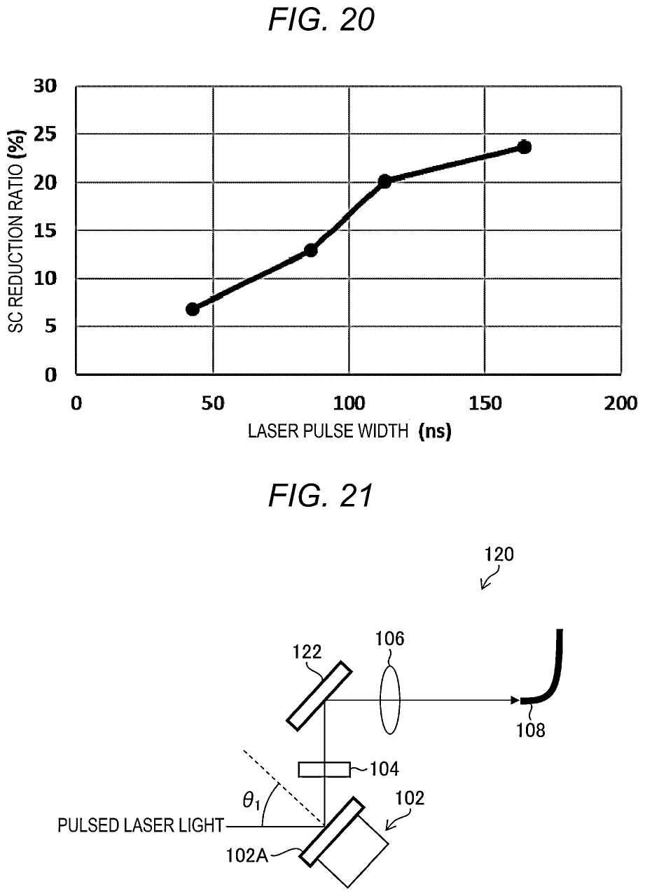

FIG. 20 shows the relationship between the pulse width of the pulsed laser light and an SC reduction ratio. The SC reduction ratio is the ratio in accordance with which the speckle contrast SC decreases due to the vibrational deformation of the deformable mirror 102, and is expressed in %. The SC reduction ratio is defined by Expression (3) below, where SC_{OFF} represents the speckle contrast in the case where the reflective surface 102A of the deformable mirror 102 is not vibrated or deformed, and SC_{ON} represents the speckle contrast in the case where the reflective surface 102A of the deformable mirror 102 is vibrated and deformed.

SC reduction ratio=(SC_{OFF}−SC_{ON})/SC_{OFF}×100 (3)

The pulse width of the pulsed laser light can be changed by adjusting the delay optical path length of the OPS 60. In FIG. 20, the data in the vicinity of a pulse width of 40 ns is data achieved when no OPS 60 is used, and indicates that the SC reduction ratio increases as the pulse width of the pulsed laser light is increased by changing the optical path length of the OPS 60. As described above, according to the excimer laser apparatus 2, placing the deformable mirror 102 downstream from the OPS 60 can provide a synergistic speckle reduction effect achieved by the OPS 60 and the deformable mirror 102.

The SC reduction ratio is believed to increase when the vibrational deformation of the reflective surface 102A occurs in a cycle shorter than the pulse width and the amplitude of the vibrational deformation increases.

According to the excimer laser apparatus 2, the vibrational deformation of the reflective surface 102A starts before the pulsed laser light is incident thereon, whereby the pulsed laser light can be reflected under stable vibrational deformation. According to the excimer laser apparatus 2, the reflective surface 102A is vibrated and deformed at the same timing whenever each pulse of the pulsed laser light is issued, whereby the same speckle reduction effect is achieved on a pulse basis. That is, the spectral waveform is stabilized as compared with a case where the reflective surface 102A is vibrated at different timings on a pulse basis, resulting in contribution to improvement in spectrum measurement precision.

According to the excimer laser apparatus 2, the diffuser 104 is disposed downstream from the deformable mirror 102 in the optical path of the pulsed laser light, whereby the illuminance or intensity distribution of the pulsed laser light can be appropriately homogenized. According to the excimer laser apparatus 2, use of the corroded diffuser 104 can suppress attenuation of the pulsed laser light. Furthermore, according to the excimer laser apparatus 2, the diffuser 104 is disposed at the position where the pulsed laser light is focused by the focusing lens 73 when the reflective surface 102A is not deformed, whereby attenuation of the pulsed laser light can be suppressed.

According to the excimer laser apparatus 2, since the speckles produced by the pulsed laser light are changed before the pulsed laser light enters the optical fiber 108, the durability of the optical fiber 108 can be improved as compared with a case where the speckles are changed after the pulsed laser light exits out of the optical fiber 108. According to the excimer laser apparatus 2, the numerical aperture of the focusing lens 106 is smaller than or equal to the numerical aperture of the optical fiber 108, whereby the pulsed laser light can efficiently enter the optical fiber 108.

According to the excimer laser apparatus 2, when the optical fiber 108 (example of homogenizer) including at least one of the core 108A having a polygonal cross-sectional shape and the bundle-type core 108A is used, the effect of homogenizing the illuminance or intensity distribution of the pulsed laser light can be enhanced.

### 5. Second Embodiment

### 5.1 Configuration

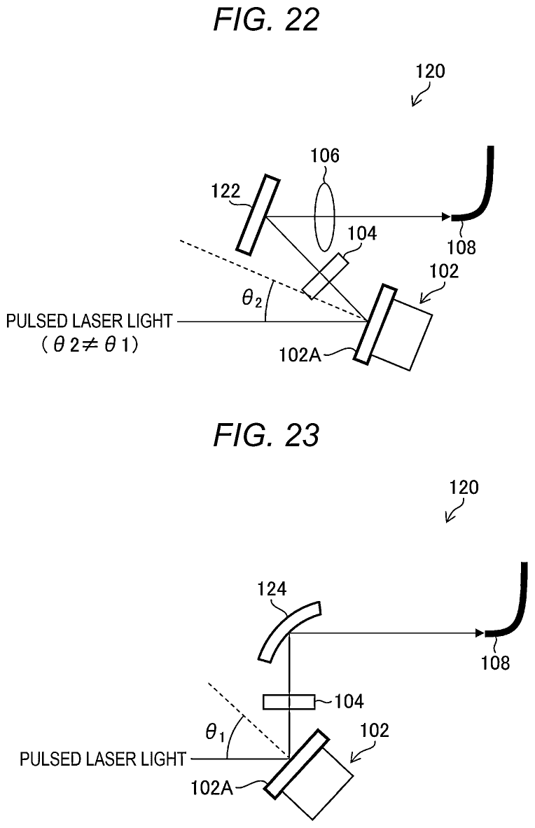

FIGS. 21 and 22 show examples of part of the configuration of a light transmission unit 120 according to a second embodiment. The light transmission unit 120 includes the BS 71, the highly reflective mirror 72, and the focusing lens 73 (see FIG. 16 for each component), none of which is shown. The light transmission unit 120 further includes a highly reflective mirror 122 in the optical path of the light reflected off the deformable mirror 102 in the optical path of the pulsed laser light.

The highly reflective mirror 122 is an optical element having, for example, a reflectance of 99% or higher. The highly reflective mirror 122 is disposed so as to highly reflect the pulsed laser light diffused by the diffuser 104 and cause the reflected light to enter the focusing lens 106.

The highly reflective mirror 122 may be disposed at a different angle according to the angle of incidence of the pulsed laser light incident on the reflective surface 102A. FIG. 21 shows an example of an angle of incidence 01. FIG. 22 shows an example of an angle of incidence 02, which is smaller than the angle of incidence 01. The angles of incidence 01 and 02 are each greater than 0° but smaller than or equal to 45°.

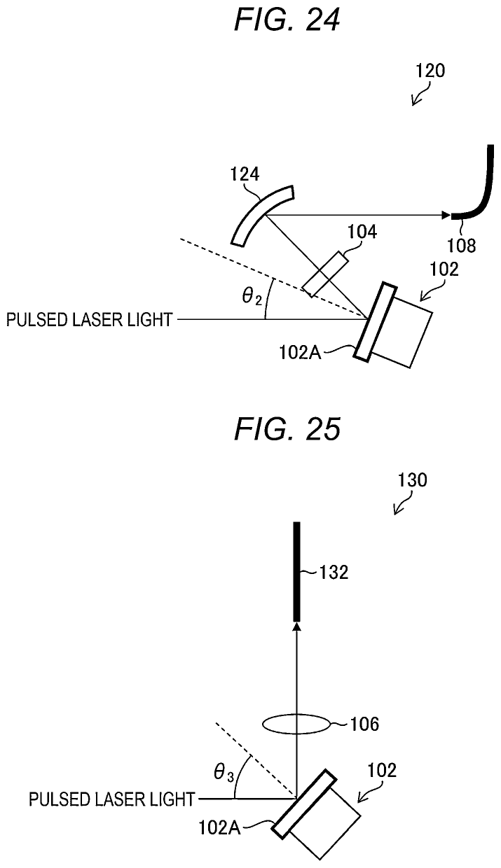

The highly reflective mirror 122 may be configured as a concave focusing mirror, and the focusing lens 106 may be omitted. FIGS. 23 and 24 show other examples of part of the configuration of the light transmission unit 120. In this example, the light transmission unit 120 includes a highly reflective concave mirror 124. The concave surface may be a spherical surface or an aspherical surface such as a parabolic surface, an off-axis parabolic surface, or an ellipsoid of revolution.

The highly reflective concave mirror 124 (example of second focusing optical element) is a concave focusing mirror having a reflectance of 99% or higher. The highly reflective concave mirror 124 is disposed so as to highly reflect and focus the pulsed laser light diffused by the diffuser 104 and cause the reflected and focused light to enter the optical fiber 108. The numerical aperture of the highly reflective concave mirror 124 is desirably smaller than or equal to the numerical aperture of the optical fiber 108.

The highly reflective concave mirror 124 may be disposed at different angles according to the angle of incidence of the pulsed laser light incident on the reflective surface 102A. FIG. 23 shows an example of the angle of incidence 01. FIG. 24 shows an example of the angle of incidence 02, which is smaller than the angle of incidence 01.

5.2 Operation

In the light transmission unit 120 shown in FIGS. 21 and 22, the pulsed laser light reflected off the reflective surface 102A of the deformable mirror 102 is diffused by the diffuser 104. The diffused pulsed laser light is highly reflected off the highly reflective mirror 122, is then focused by the focusing lens 106, and enters the optical fiber 108.

In the light transmission unit 120 shown in FIGS. 23 and 24, the pulsed laser light reflected off the reflective surface 102A of the deformable mirror 102 is diffused by the diffuser 104. The diffused pulsed laser light is highly reflected off and focused by the highly reflective concave mirror 124, and enters the optical fiber 108.

5.3 Effects and Advantages

When the configuration of the light transmission unit 100 is determined to be difficult to be implemented from the design point of view of the excimer laser apparatus 1, the light transmission unit 120 can function as an alternative configuration having a speckle noise reduction effect comparable to that provided by the light transmission unit 100 while having a different optical path of the pulse laser light.

### 6. Third Embodiment

### 6.1 Configuration

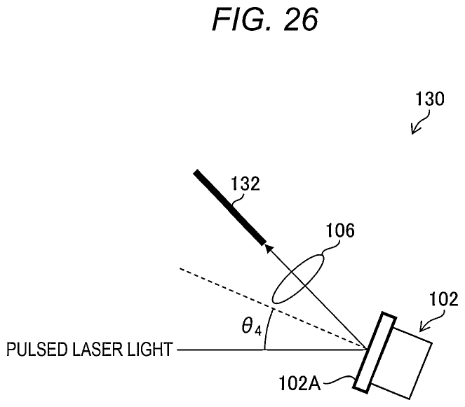

FIGS. 25 and 26 show examples of the configuration of part of a light transmission unit 130 according to a third embodiment. The light transmission unit 130 includes the BS 71, the highly reflective mirror 72, and the focusing lens 73 (see FIG. 16 for each component), none of which is shown. The light transmission unit 130 further includes an optical fiber 132 (example of homogenizer). The light transmission unit 130 differs from the light transmission unit 100 in that the light transmission unit 130 includes no diffuser 104.

The deformable mirror 102 is so disposed that the pulsed laser light incident on the reflective surface 102A enters the focusing lens 106.

The focusing lens 106 is disposed so as to focus the pulsed laser light incident thereon and cause the focused light to enter the optical fiber 132. The numerical aperture of the focusing lens 106 is desirably smaller than or equal to the numerical aperture of the optical fiber 132.

The focusing lens 106 and the optical fiber 132 may be disposed at different angles according to the angle of incidence of the pulsed laser light incident on the reflective surface 102A. FIG. 25 shows an example of an angle of incidence 03. FIG. 26 shows an example of an angle of incidence 04, which is smaller than the angle of incidence 03. The angles of incidence 03 and 04 are each greater than 0° but smaller than or equal to 45°.

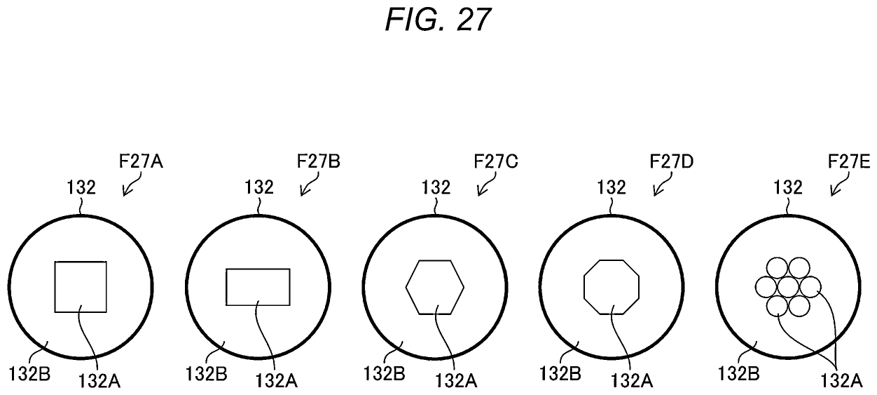

FIG. 27 shows a cross-sectional view of the optical fiber 132. The optical fiber 132 includes a core 132A, which forms a waveguide along which the pulsed laser light is guided, and a cladding 132B, which surrounds the core 132A.

F27A, F27B, F27C, and F27D in FIG. 27 show optical fibers 132 including cores 132A having square, rectangular, hexagonal, and octagonal cross-sectional shapes. F27E shown in FIG. 27 shows an optical fiber 132 including a plurality of cores 132A bundled together.

6.2 Operation

The light transmission unit 130 directly focuses the pulsed laser light reflected off the reflective surface 102A of the deformable mirror 102 with the aid of the focusing lens 106 and causes the focused light to enter the optical fiber 132.

6.3 Effects and Advantages

According to the light transmission unit 130, which uses the optical fiber 132 including at least one of the core 132A having a polygonal cross-sectional shape and the bundle-type core 132A, the illuminance homogenization effect provided by the diffuser 104 can be achieved only with the optical fiber 132.

According to the light transmission unit 130, which includes no diffuser 104, loss of the amount of light can be smaller than that in the light transmission unit 100.

Furthermore, the light transmission unit 130 requires a space smaller than that required by the light transmission unit 100 and can achieve a speckle noise reduction effect comparable to that achieved by the light transmission unit 100.

### 7. Fourth Embodiment

### 7.1 Configuration

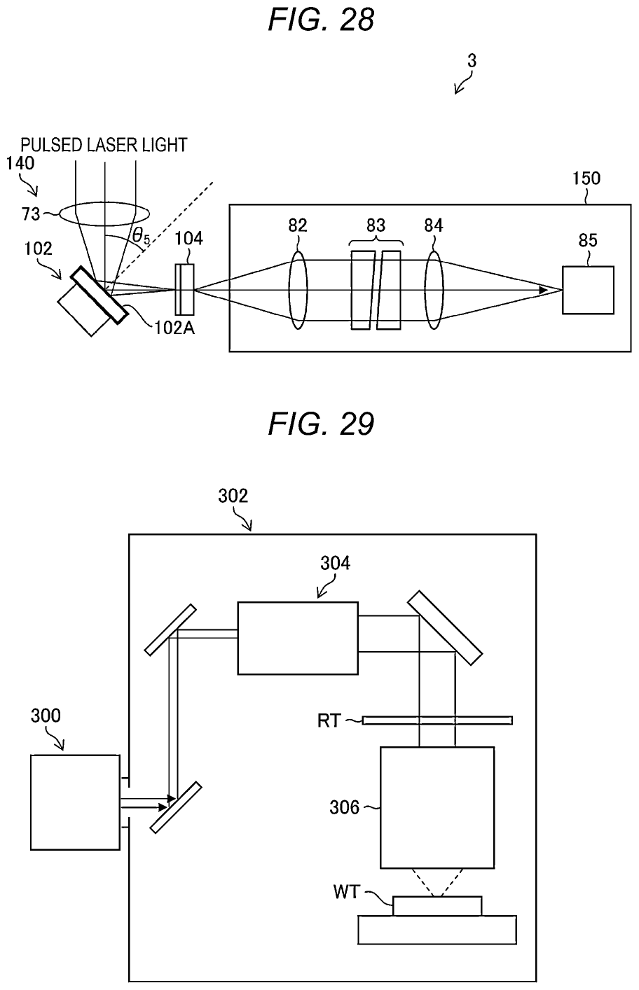

FIG. 28 shows part of the configuration of an excimer laser apparatus 3 according to a fourth embodiment. The excimer laser apparatus 3 includes a light transmission unit 140 and a spectrum measuring instrument 150.

The light transmission unit 140 includes the BS 71 and the highly reflective mirror 72 (see FIG. 16 for each component), none of which is shown. The light transmission unit 140 differs from the light transmission unit 100 in that the light transmission unit 140 includes no focusing lens 106 nor the optical fiber 108. The deformable mirror 102 is so disposed that an angle of incidence θ₅ of the pulsed laser light incident from the focusing lens 73 is greater than 0° but smaller than or equal to 45°.

The spectrum measuring instrument 150 differs from the spectrum measuring instrument 80 in that the spectrum measuring instrument 150 includes no fiber swinging mechanism 81.

7.2 Operation

The excimer laser apparatus 3 causes the pulsed laser light reflected off the reflective surface 102A of the deformable mirror 102 to pass through the diffuser 104, which diffuses the pulsed laser light, and causes the diffused light to directly enter the spectrum measuring instrument 150.

7.3 Effects and Advantages

According to the light transmission unit 140, the homogenized pulsed laser light is caused to enter the spectrum measuring instrument 150 without passing through the optical fiber 108, whereby the loss of the amount of light can be smaller than that in the light transmission unit 100.

Furthermore, the light transmission unit 140 requires a space smaller than that required by the light transmission unit 100 and can achieve a speckle noise reduction effect comparable to that achieved by the light transmission unit 100.

### 8. Method for Manufacturing Electronic Devices

FIG. 29 schematically shows an example of the configuration of the exposure apparatus 302. The method for manufacturing electronic devices is realized by an excimer laser apparatus 300 and the exposure apparatus 302.

The excimer laser apparatus 300 may include any of the excimer laser apparatuses 1,2, and 3 described in the embodiments.

The pulsed laser light outputted from the excimer laser apparatus 300 is inputted to the exposure apparatus 302 and used as exposure light.

The exposure apparatus 302 includes an illumination optical system 304 and a projection optical system 306. The illumination optical system 304 illuminates a reticle pattern on a reticle stage RT with the pulsed laser light having entered the exposure apparatus 302 from the OPS 60. The projection optical system 306 performs reduction projection on the pulsed laser light having passed through the reticle to bring the pulsed laser light into focus on a workpiece that is not shown but is placed on a workpiece table WT. The workpiece is a light sensitive substrate onto which a photoresist has been applied, such as a semiconductor wafer. The exposure apparatus 302 translates the reticle stage RT and the workpiece table WT in synchronization with each other to expose the workpiece to the pulsed laser light having reflected the reticle pattern. Semiconductor devices can be manufactured by transferring a device pattern onto the semiconductor wafer in the exposure step described above. The semiconductor devices are an example of the “electronic devices” in the present disclosure.

### 9. Others

An excimer laser apparatus has been used as the MO 10 of the excimer laser apparatus 2, and a solid-state laser apparatus may instead be used. Even when a solid-state laser apparatus is used as the MO 10, the excimer laser apparatus 2 can be considered as a narrowed-line gas laser apparatus.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A light transmission unit comprising:
a deformable mirror including a deformer configured to deform a reflection surface during a period for which the reflection surface reflects pulsed laser light; and
a homogenizer configured to homogenize the pulsed laser light reflected off the deformable mirror.

2. The light transmission unit according to claim 1,
wherein the deformer is configured to periodically deform a shape of the reflective surface within one pulse of the pulsed laser light.

3. The light transmission unit according to claim 1,
wherein an angle of incidence of the pulsed laser light incident on the deformable mirror is smaller than or equal to 45°.

4. The light transmission unit according to claim 1,
wherein the homogenizer includes a diffuser.

5. The light transmission unit according to claim 4,
wherein the diffuser is a corroded diffuser.

6. The light transmission unit according to claim 4,
further comprising a first focusing optical element configured to focus the pulsed laser light at the diffuser.

7. The light transmission unit according to claim 6,
wherein the first focusing optical element is disposed in a position so that the first focusing optical element focuses the pulsed laser light at the diffuser via the deformable mirror.

8. The light transmission unit according to claim 4,
further comprising a reflective mirror in an optical path of the pulsed laser light homogenized by the diffuser.

9. The light transmission unit according to claim 8,
wherein the reflective mirror is a focusing mirror.

10. The light transmission unit according to claim 1,
wherein the homogenizer includes an optical fiber including at least one of a core having a polygonal cross-sectional shape or a bundle-type core.

11. The light transmission unit according to claim 10,
further comprising a second focusing optical element configured to focus the pulsed laser light at the optical fiber.

12. The light transmission unit according to claim 11,
wherein a numerical aperture of the second focusing optical element is smaller than or equal to a numerical aperture of the optical fiber.

13. The light transmission unit according to claim 12,
further comprising a first processor configured to start driving the deformer in synchronization with generation of the pulsed laser light.

14. The light transmission unit according to claim 13,
wherein the first processor is configured to stop driving the deformer a fixed period after the first processor starts driving the deformer.

15. A laser apparatus comprising:
a laser oscillator configured to output pulsed laser light;
a deformable mirror including a deformer configured to deform a reflective surface;
a first processor configured to drive the deformer during a period for which the reflective surface reflects the pulsed laser light;
a homogenizer configured to homogenize the pulsed laser light reflected off the deformable mirror; and
a spectrum measuring instrument configured to measure a spectrum of the pulsed laser light homogenized by the homogenizer.

16. The laser apparatus according to claim 15,
further comprising an optical pulse stretcher configured to stretch a pulse width of the pulsed laser light and cause the pulsed laser light to exit toward the deformable mirror.

17. The laser apparatus according to claim 15,
wherein the spectrum measuring instrument includes
an etalon on which the pulsed laser light is incident, and
a sensor configured to acquire a fringe pattern produced by the etalon.

18. The laser apparatus according to claim 17,
further comprising a second processor configured to calculate the spectrum of the pulsed laser light from the fringe pattern.

19. The laser apparatus according to claim 18,
further comprising a controller configured to control the laser oscillator based on the calculated spectrum.

20. A method for manufacturing electronic devices, the method comprising:
generating pulsed laser light by using a laser apparatus;
outputting the pulsed laser light to an exposure apparatus; and
exposing a light sensitive substrate to the pulsed laser light in the exposure apparatus to manufacture the electronic devices,
the laser apparatus including
a laser oscillator configured to output the pulsed laser light,
a deformable mirror including a deformer configured to deform a reflective surface,
a first processor configured to drive the deformer during a period for which the reflection surface reflects the pulsed laser light,
a homogenizer configured to homogenize the pulsed laser light reflected off the deformable mirror, and
a spectrum measuring instrument configured to measure a spectrum of the pulsed laser light homogenized by the homogenizer.
